(19) United States
(12) Patent Application Publication
(10) Pub. No.: US 2025/0333836 A1
(43) Pub. Date: Oct. 30, 2025

(54) MULTIZONE HEATER FOR MAGNETIC MEDIA

(71) Applicant: Seagate Technology LLC, Fremont, CA (US)

(72) Inventors: Mitchell Tomio INOUYE, San Jose, CA (US); ChunWai Joseph TONG, San Jose, CA (US); Eric Aguila FERNANDEZ, Union City, CA (US); Wei-Heng HSU, Fremont, CA (US); Jessica Pei-Jun SOONG, Sunnyvale, CA (US)

(21) Appl. No.: 18/645,156

(22) Filed: Apr. 24, 2024

(51) Int. Cl. C23C 14/54; G11B 5/851; H05B 3/06

(52) U.S. Cl. CPC C23C 14/541; H05B 3/06; G11B 5/851; H05B 2203/014; H05B 2203/037

(57) ABSTRACT

A heater for a disc substrate in a deposition system. The heater has a central first heating zone and an annular second heating zone around the first heating zone. Each of the heating zones has an independently controllable power supply to allow, for example, the second heating zone to be heated to a temperature at least 10° C. greater than the first heating zone.

### BACKGROUND

Disc drives are a common data storage application. There is always a desire for increased data storage density and increased reading and writing speed from that storage.

The increasing demands for higher recording density impose increasingly greater demands on thin film magnetic recording media in terms of coercivity (Hc), magnetic remanence (Mr), coercivity squareness (S*), medium noise (e.g., signal-to-medium noise ratio (SMNR)), and narrow track recording performance. It can be extremely difficult to produce a magnetic recording medium satisfying such demanding requirements.

The recording density can be increased by decreasing the medium noise, by maintaining very fine magnetically decoupled grains in the magnetic layer of the magnetic medium. Medium noise is a dominant factor restricting increased recording density of high-density magnetic hard disc drives, and is attributed primarily to irregular grain size and intergranular exchange coupling in the magnetic layer. To increase density, noise can be minimized by suitable microstructure control of the magnetic layer and other layers of the magnetic medium.

The microstructure and uniaxial anisotropy of the layers of the magnetic medium are determined by both the composition of the layers as well as the conditions for depositing the layers. The microstructure and uniaxial anisotropy can be controlled in several ways. One method is to anneal after deposition while applying a magnetic field. However, this method causes complications in the disc manufacturing process, because the application of heat after or during the manufacturing process is difficult. Another method is to heat the substrate before the coatings are applied.

### SUMMARY

This disclosure is directed to a heater to heat a magnetic media (e.g., disc) substrate in a deposition system, such as an ion beam deposition system, prior to and/or during the application of coatings on the substrate. During heating, the heater is in close proximity to the substrate and has at least two zones, at least one zone for an outer section of the disc and at least one zone for an inner section of the disc. The zones can be concentrically positioned in relation to each other. The zone can have different temperatures during the heating process; having a higher temperature at the outer circumference or edge of the substrate facilitates obtaining a consistent temperature across the substrate. The zones can be independently controlled.

One particular implementation provided herein is a heater for a substrate in a deposition system, the heater having a central first heating zone and an annular second heating zone around the first heating zone, each of the heating zones having a power supply, with the heating zones independently controllable.

Another particular implementation provided herein is a heater for a substrate in a deposition system, the heater having a radius and a central first heating zone having an outer radius and an annular second heating zone having an inner radius, the inner radius greater than or equal to the outer radius, with each of the heating zones having an independently controllable power supply.

Another particular implementation provided herein is a heater for a substrate in a deposition system, the heater having a heating element having a power supply and defining a first heating zone and a second heating zone, with the heating element configured to provide a higher temperature in the second heating zone than the first heating zone. The first heating zone may be a central heating zone and the second heating zone may be an annular heating zone around the central heating zone.

Another particular implementation provided herein is a deposition system having a chamber with at least one multiple-zone heater therein. The multiple-zone heater has a first heating zone and a second heating zone, each of the heating zones having a power supply, with the heating zones independently controllable. The first heating zone may be a central heating zone and the second heating zone may be an annular heating zone around the central heating zone. In other implementations, the multiple-zone heater has a first heating zone and a second heating zone heated by a heating element, with the heating element in the second heating zone configured to provide a higher temperature than in the first heating zone under the same input current.

Another particular implementation provided herein is a method of heating a disc substrate in a deposition system. The method includes bringing a first side of the disc substrate in close proximity to a first heater comprising a central first heating zone having an outer radius and an annular second heating zone having an inner radius, the inner radius greater than or equal to the outer radius, with each of the heating zones having an independently controllable power supply. The method can further include bringing a second side of the disc substrate into close contact with a second heater comprising a central first heating zone having an outer radius and an annular second heating zone having an inner radius, the inner radius greater than or equal to the outer radius, with each of the heating zones having an independently controllable power supply.

This disclosure provides methods of heating a disc substrate in a deposition system with any of the heaters described herein.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. These and various other features and advantages will be apparent from a reading of the following detailed description.

### BRIEF DESCRIPTION OF THE DRAWING

The described technology is best understood from the following Detailed Description describing various implementations read in connection with the accompanying drawing.

FIG. 1 is a top view of a magnetic media disc drive.

FIG. 2 is a schematic side view of a disc from a disc drive.

FIG. 3 is a schematic side view of a chamber having a disc heater.

FIG. 4 is a schematic top view of a single zone disc heater.

FIG. 5 is a schematic top view of a multiple zone disc heater.

FIGS. 6A through 6E are schematic top views of examples of heaters having multiple independent heating zones.

FIG. 7 is a schematic top view of another multiple zone disc heater.

### DETAILED DESCRIPTION

As indicated above, this description is directed to a multiple zone heater to heat a magnetic media (e.g., disc) substrate in a deposition system, such as an ion beam deposition system, prior to applying coatings on the substrate. The multiple zone heater has a central first heating zone and an annular second heating zone around the first heating zone. Each of the heating zones can have different heating capabilities to allow, for example, the second heating zone to have a temperature at least 5° C. greater than the first heating zone, in some embodiments at least 50° C. greater, and in other embodiment at least 100° C. greater than the first heating zone. The heating zones can each have an independently controllable power supply.

In the following description, reference is made to the accompanying drawing that forms a part hereof and in which is shown by way of illustration at least one specific implementation. The following description provides additional specific implementations. It is to be understood that other implementations are contemplated and may be made without departing from the scope or spirit of the present disclosure. The following detailed description, therefore, is not to be taken in a limiting sense. While the present disclosure is not so limited, an appreciation of various aspects of the disclosure will be gained through a discussion of the examples, including the figures, provided below. In some instances, a reference numeral may have an associated sub-label consisting of a lower-case letter to denote one of multiple similar components. When reference is made to a reference numeral without specification of a sub-label, the reference is intended to refer to all such multiple similar components.

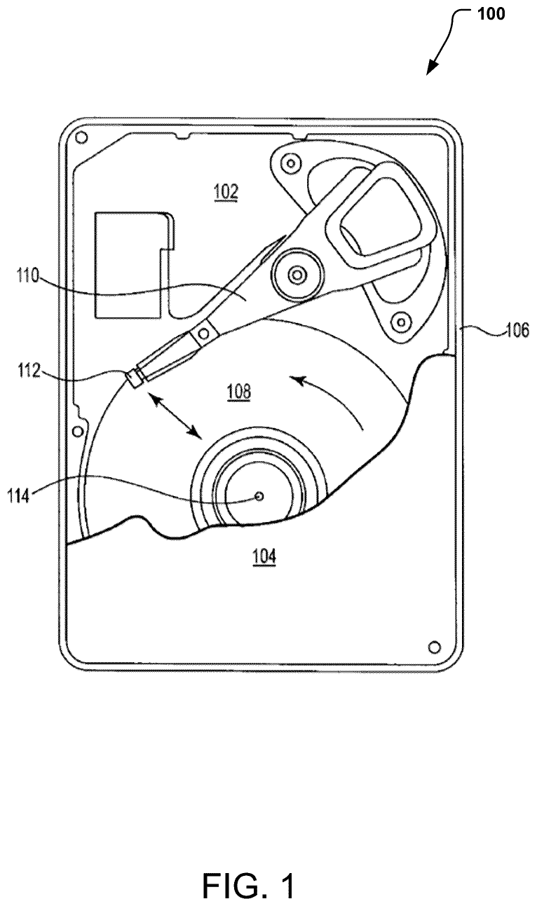

Referring to FIG. 1, an exemplary magnetic disc drive 100 is schematically illustrated. Disc drive 100 includes a base 102 and a top cover 104, shown partially cut away. The base 102 combines with the top cover 104 to form the housing 106, in which is located one or more rotatable magnetic data storage media or discs 108. The magnetic storage media 108 are attached to a spindle 114 for co-rotation about a central axis. It should be noted that a pack of multiple discs or media 108 is utilized in some embodiments, and only a single disc or medium 108 is used in other embodiments. Each disc or medium surface has an associated bead or slider 112 which is mounted adjacent to and in communication with its corresponding disc or media 108. The head or slider 112 includes a data recording transducer and a data reading transducer (also referred to as read/write heads, and the like), which read and write data to the storage disc or media 108. In the example shown in FIG. 1, the head or slider 112 is supported by an actuator assembly 110 composed of various elements that are known in the field. The actuator assembly 110 shown in FIG. 1 is of the type known as a rotary moving coil actuator and includes a voice coil motor to rotate actuator assembly 110 with its attached slider 112 to position the slider 112 and its read/write heads over a desired data track along an arcuate path between an inner diameter and an outer diameter of disc of media 108.

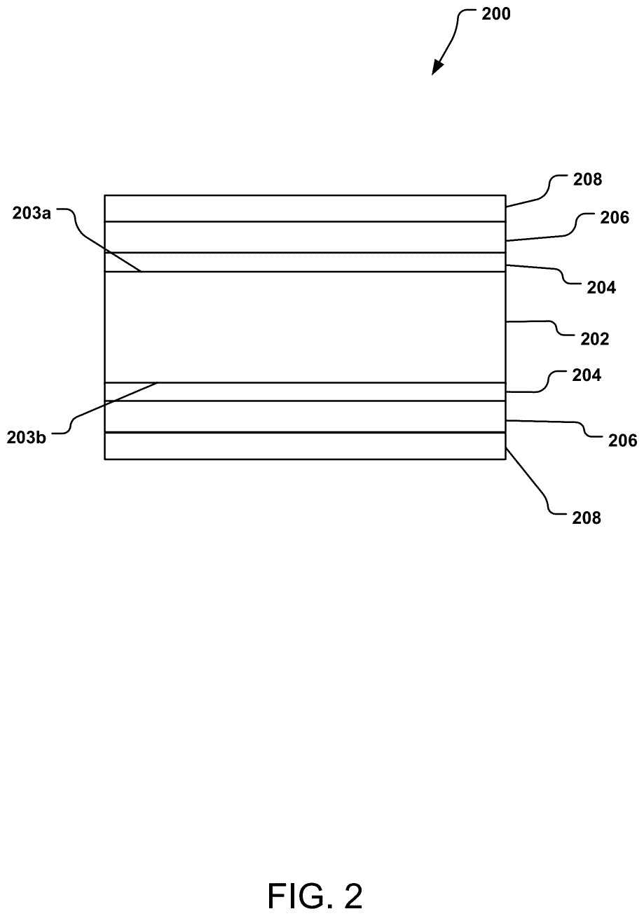

A cross sectional view of an example recording disc or medium is depicted in FIG. 2 as 200. The disc or medium 200 has a non-magnetic base substrate 202 having a first side 203a and an opposite side 203b. Sequentially deposited on each side 203 is a soft magnetic underlayer 204 such as chromium (Cr) or Cr-alloy, a hard magnetic layer 206 e.g., comprising a cobalt (Co)-alloy, and a protective overcoat 208 e.g., containing carbon. Some designs include a lubricant topcoat (not shown) over the protective overcoat 208. The underlayer 204, the magnetic layer 206 and the protective overcoat 208 can be deposited by sputtering techniques or other suitable techniques.

It is noted that in some applications the terms “recording layer” and “magnetic layer” are equivalent and denote the same layer. A soft underlayer is relatively thick compared to other layers. Any layers between the soft underlayer and the recording layer are called interlayers or intermediate layers. An interlayer can be made of more than one layer of non-magnetic materials. The purpose of the interlayer is to prevent an interaction between the soft magnetic underlayer and recording layer. An interlayer could also promote the desired properties of the recording layer. Other layers that may be present have been named as “underlayers,” “seed layers,” “sub-seed layers,” and “buffer layers.”

Almost all the manufacturing of the disc media occurs in clean rooms where the atmosphere is strictly controlled to be free of contaminant. After one or more cleaning processes, the substrate has an ultra-clean surface and is ready for the deposition of layers of magnetic media on the substrate. The apparatus for depositing all the layers of the disc or media is typically a sputtering system, and could be a static sputter system or a pass-by system, where all the layers except the lubricant are commonly deposited sequentially inside a suitable vacuum environment.

The non-magnetic base substrate 202 is commonly an alloy, such as aluminum-magnesium (Al—Mg), or glass. To facilitate the application of the layers onto the substrate 202, the substrate 202 is heated above room temperature (e.g., to at least 500° C., sometimes to at least 750° C.) prior to application of the first layer. In many situations, the substrate 202 is heated by supporting the substrate 202 on a heated (or heatable) support carrier. In other situations, the substrate 202 is brought into close proximity to a heated (or heatable) platen. Depending on the design, the heating of the substrate 202 may be via a heater on one side (e.g., the side 203a) or both sides (e.g., the side 203a and the side 203b). Although inefficient, the entire chamber in which the deposition occurs may be heated, e.g., by heaters positioned on the walls or otherwise within the chamber.

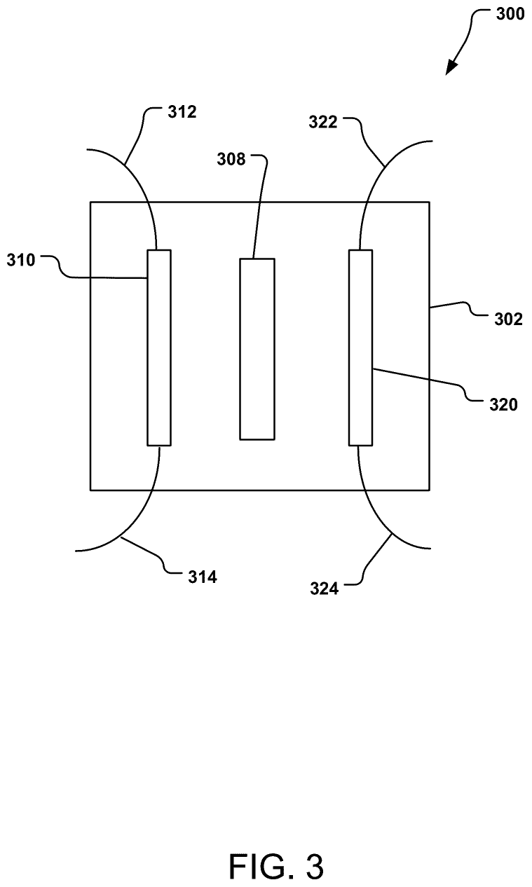

FIG. 3 schematically shows a deposition system 300 having two heaters therein. The system 300 includes a chamber 302 in which a substrate 308 is supported (the specific support not shown in FIG. 3), with a first heater 310 and a second heater 320, one heater on each side of the substrate 308. In alternate designs, the chamber 302 may have only one heater. The heaters 310, 320 and substrate 308 are located and supported in the chamber 302 so that the substrate 308 can be moved, in close proximity, in between the heaters 310, 320 and out from between the heaters 310, 320.

Each of the heaters 310, 320 is a multiple zone heater, having at least a first zone and a second zone, the zones not seen in FIG. 3. The first heater 310 has a first electrical source 312 for the first zone and a second electrical source 314 for the second zone; similarly, the second heater 320 has a first electrical source 322 for the first zone and a second electrical source 324 for the second zone. The first source 312 is independently controllable from the second source 314, and the first source 322 is independently controllable from the source 312 and the second source 324, which is independently controllable from the second source 314. In other words, each of the four zones is independently controllable.

The heaters 310, 320 are exactly or approximately the same size (e.g., diameter, or radius) as the substrate 308; in some embodiments, the heaters 310, 320 are slightly larger than the substrate 308, resulting in the heaters 310, 320 extending (e.g., 1 mm) past the outer circumference of the substrate 308; in other words, the heaters 310, 320 have a radius that is greater (e.g., 1 mm greater) than the radius of the substrate 308.

In use, the substrate 308 is brought into close proximity between the heaters 310, 320 so that the first heating zone heats the central region of the substrate 308 and the second heating zone heats the outer circumference region of the substrate 308. The outer or second heating zone can be configured to obtain a temperature to at least 10° C. greater, in some implementations at least 50° C. or 100° C. greater, and sometimes at least 150° C. greater, than the central or first heating zone, due to the independent power sources 312, 314, 322, 324 for the four zones. In some embodiments, the same controller can be used to independently control the power sources 312, 314, 322, 324. Providing a higher temperature at the outer circumferences results in a constant temperature gradient across the substrate 308.

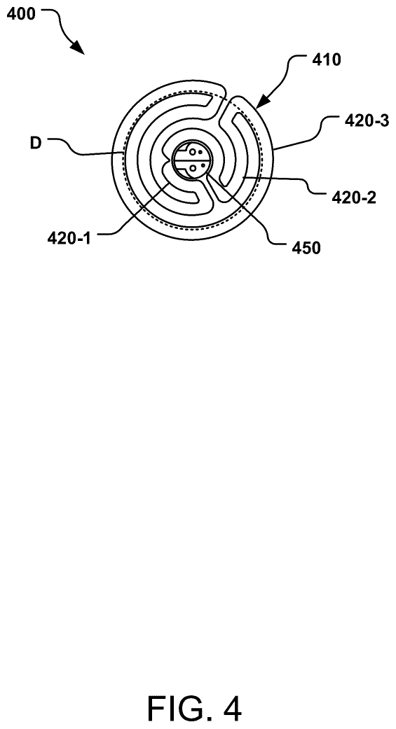

FIG. 4 shows a heater 400 that could be used in the arrangement of FIG. 3, with the heater 400 having a single heating zone. The heater 400 has a heating element such as a filament 410 configured in three generally concentric rings 420-1, 420-2, 420-3 having a central power supply 450. A disk D is shown, in phantom, operably positioned relative to the heater 400. This heater 400 has a single heating zone and one power supply 450 provides power to the heating element and controls the entire heating area. It is noted that the rings 420-1, 420-2, 420-3 do not form a fully complete, 360 degree circle, but rather, the rings extend less than the full 360 degrees, e.g., about 350-355 degrees. As used herein, although the term “ring” or similar is used, it is not intended that a ring form a full 360 degree circle; a ring can be, e.g., between 270 degrees and 359 degrees and still be considered a ring.

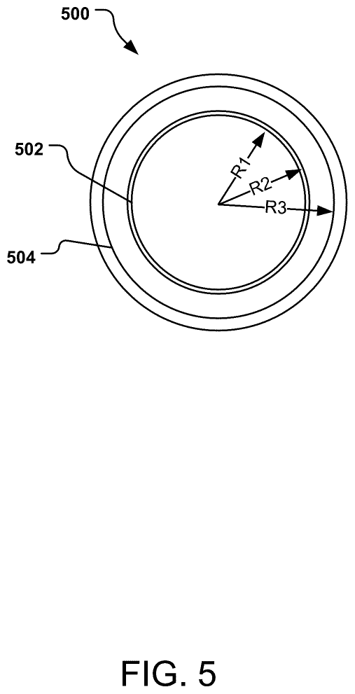

FIG. 5 shows a heater 500 that could alternately be used in the arrangement of FIG. 3, the heater 500 in accordance with this disclosure, having multiple heating zones. The heater 500 has a first zone 502 and a second zone 504. A first power supply (not shown) supplies power to the first zone 502 and a second power supply (not shown) supplies power to the second zone 504; the power supplies are independently controlled. The first zone 502 is centralized with the second zone 504 being an annular ring around the first zone 502. The first zone 502 may encompass the center of the heater, as in FIG. 5, or there may be a central spot that is not included in the first zone 502 (that is, the first zone 502 is annular). The first zone 502 has an outer radius R1. The second zone 504 has an inner radius R2 and an outer radius R3. In some embodiments, as shown in FIGS. 5, R1 and R2 are unequal, resulting in an annular gap between the first zone 502 and the second zone 504; in other embodiments, the zones 502, 504 may abut (that is, R1 and R2 are the same). In some embodiments, the zone 504 may extend to the outer circumference of the heater (that is, R3 extends to the periphery of the heater 500).

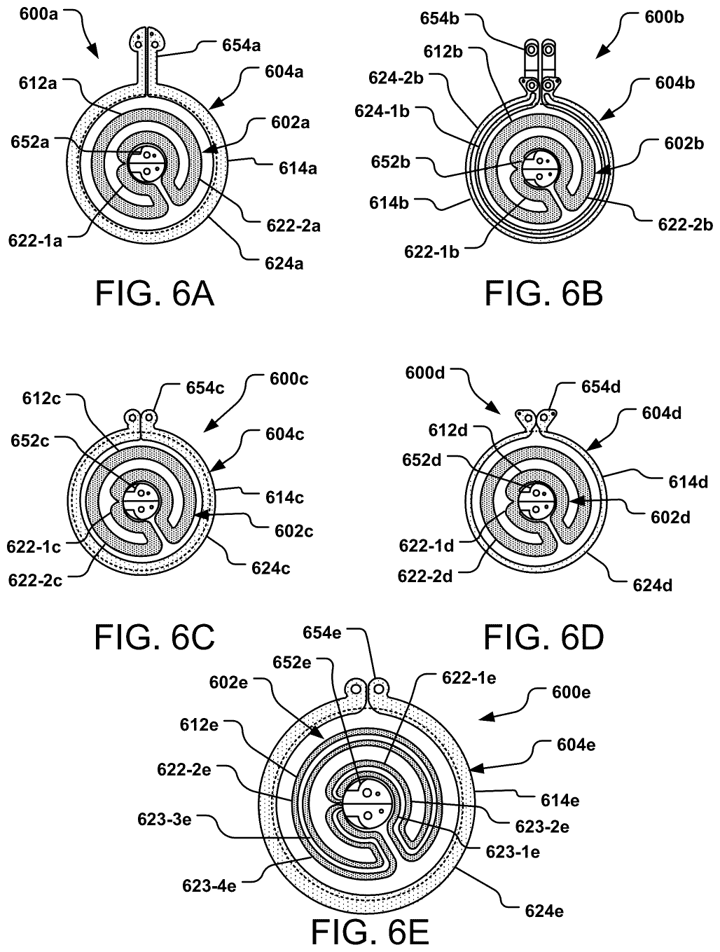

FIGS. 6A through 6E show various embodiments of multiple zone heaters having two independent zones, each zone having its own, independently controllable heating element. The two zones can be heated to the same or to different temperatures. In each of these embodiments, a first zone is present at an inner region of the heater and a second zone is present at an outer region of the heater, concentrically positioned around the first zone. Together, the first zone and the second zone define a heating area. A disk substrate D, in phantom, is shown overlying each of the heaters, in some embodiments the heater having a larger diameter than the substrate.

In FIG. 6A, a heater 600a has a first zone 602a and a second zone 604a, each of the zones 602a, 604a have a heating element such as a filament 612a and a filament 614a, respectively. The filament 612a of the first zone 602a is, generally, two concentric and connected rings 622-1a and 622-2a, having central power supply 652a. The filament 614a of the second zone 604a has a single, annular ring 624a at the outer diameter (outer edge) of the heater 600a, connected to a circumferentially external power source 654a. The heating filaments 612a, 614a in both the first zone 602a and the second zone 604a have the same thickness. The outer circumference of the disc substrate is at or close to the inner edge of the filament 614a (e.g., the disc substrate has a radius same as or close to the inner radius of the filament 614a).

As indicated above and as used here, although the term “ring” or “rings” is used, the ring does not form a full 360 degree circle, but rather, the ring extends less than a full 360 degrees.

An alternate heater 600b is shown in FIG. 6B having a first zone 602a and a second zone 604b, with the first zone 602b have a heating element such as a filament 612b connected to a power source 652b in the same pattern as the first zone filament 612a in the heater 600a of FIG. 6A. In the heater 600b, however, the filament 614b of the second zone 604b, connected to a power source 654b, forms two annular rings 624-1b and 624-2b and has a lesser width or thickness than the filament 612b of the first zone 602b. This heater 600b is designed to have the inner annular ring 624-1b positioned internal to the outer circumference of the disc substrate (e.g., positioned at a radius less than the radius of the substrate) being heated by the heater 600b and the outer annular ring 624-2b positioned at and/or partially outside of the outer circumference of the disc substrate (e.g., positioned at a radius equal to or greater than the radius of the substrate).

In FIG. 6C, a heater 600c is similar to the heater 600a, having a first zone 602c and a second zone 604c. The first zone 602c has a heating element such as a filament 612c forming two generally concentric rings 622-1c and 622-2c having central power supply 652c. The second zone 604c has a filament 614c that is a single, annular ring 624c at the outer diameter (outer edge) of the heater 600c, connected to a circumferentially external power source 654c. The heating filaments 612c, 614c have the same thickness. In this design, however, the outer circumference of the disc substrate is positioned on the filament 614c of the second zone 604c so that the filament 614c is partially inside the outer circumference and partially outside of the outer circumference (e.g., positioned at a radius less than, equal to and greater than the radius of the substrate); in some embodiments, the outer circumference of the disc substrate is radially centered on the filament 614c. Also in this design, compared to the heater 600a, the radial distance between the filament 612c and the filament 614c is less than the distance between the filament 612a and the filament 614a of the heater 400a.

In FIG. 6D, a heater 600d is similar to the heater 400a, having a first zone 402d and a second zone 404d. The first zone 602d has a heating element such as a filament 612d forming two generally concentric rings 622-1d and 622-2d, having central power supply 652d. The second zone 604d has a filament 614d that is a single, annular ring 624d at the outer diameter (outer edge) of the heater 600d, connected to a circumferentially external power source 654d. In this design, the second heating element 614d has a radial thickness that is less than that of the first heating element 612d. The outer edge or circumference of the disc substrate is even with the outer edge of the second filament 614d of the second zone 604d; that is the outer radius of the disc substrate is the same as the outer radius of the filament 614d.

Another heater 600e, in FIG. 6E, is similar to the heater 600a, having a first zone 602e with a filament 612e and a second zone 604e with a filament 614e. Unlike the previous heater designs, the filament 612e of the first zone 602e can be described as a split filament forming two generally concentric rings 622-1e and 622-2e; or the filament 612e can be described as a thin filament forming four generally concentric rings 623-1e, 623-2e, 623-3e, 623-4e. The filament 612e has a central power supply 652e. The filament 614e of the second zone 604e has a single, annular ring 624e at the outer diameter (outer edge) of the heater 600e, connected to a circumferentially external power source 654e.

For all heaters having multiple heat zones, the power sources 652, 654 for the zones 602, 604, respectively, can be independently adjusted to control the power to the heating elements (e.g., the filaments 612, 614) to affect the temperature gradient across the heater and across the disc substrate. In some embodiments, it is desired to have a consistent (e.g., essentially the same) temperature across the entire disc substrate. In other embodiments, a higher temperature is desired at the second (outer) zone (e.g., the zone 604).

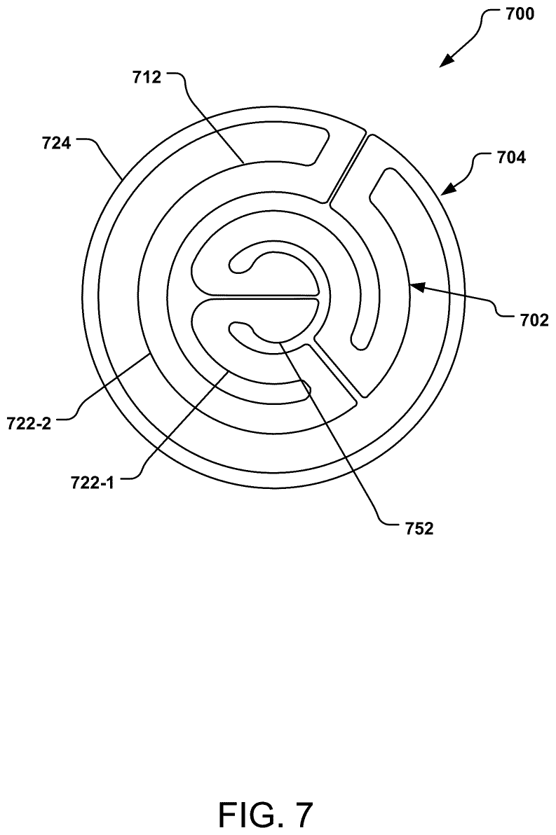

FIG. 7 shows another heater 700 having multiple heating zones, however having only one heating element and one power supply and power control element.

The heater 700 has a first zone 702 and a second zone 704, both which are heated by a heating element such as a filament 712. The filament 712 forms two generally concentric rings 722-1 and 722-2 with a central power supply 752. The filament 712 also forms a single annular ring 724 at the outer diameter (outer edge) of the heater 700 that is the second zone 704. The filament 712 in the second zone 704 and the ring 724 has a smaller width, or cross-sectional area, than the filament 712 in the first zone 702 and the rings 722. By reducing the available filament area in the second zone 704, the resistance increases. Upon application of power (current) to the entire filament 712, the temperature is greater in the second zone 704 than in the first zone 702, due to this higher resistance.

In some designs, either the entire heating element (e.g., the filament 614, 712) or a portion of the heating element forming the second zone 604, 704 is at or outside of the outer edge of the substrate (e.g., has a radius equal to or greater than the radius of the substrate). Having a heating element at or proximate the circumference provides heating of the substrate where historically a large amount of heat loss is experienced, due to the exposed outer edge of the substrate.

The inner zone (e.g., the first zone 602, 702) occupies at least 50% of the diameter or radius of the heater, with the outer zone (e.g., the second zone 604, 704) occupying no more than 50% of the diameter or radius from the circumference. In some designs, the inner zone occupies at least 75% or at least 80% of the diameter or radius. Additionally or alternately, the inner zone (e.g., the first zone 602, 702) occupies at least 25% of the total heating surface area of the heater (e.g., the heater 600, 700), in some designs at least 50% of the total heating surface area or at least 60%. A surface area ratio for the inner zone (e.g., zone 602, 702) to the outer zone (e.g., zone 604, 704) is in the range of 1:3 to 3:1, in some embodiments 1:2 to 2:1, and in other embodiments about 1:1.

A heating element or filament, whether for the first zone 602, 702 or the second zone 604, 704, occupies at least 25% of the surface area of its respective zone, in some embodiments at least 40% or at least 50%. The surface area unoccupied by the heating element or filament may be, for example, an annular region between rings or coils of the element or filament.

As depicted in the various embodiments above, one or both of the zones 602, 702, 604, 704 can have more than one ring 622, 722, 624, 724 of the respective heating element. As indicated above, the rings 622, 722, 624, 724 may not form a fully complete, 360 degree circle, but rather, extend less than the full 360 degrees, e.g., about 350-355 degrees. Although the term “ring” or similar is used, it is not intended that a ring form a full 360 degree circle; a ring can be, e.g., between 270 degrees and 359 degrees and still be considered a ring. Additionally, rather than discrete rings, the filament can be coiled or wrapped. The number of rings, coils or wraps, as well as the spacing between adjacent rings, coils or wraps, can be varied to achieve the desired heating gradient on the heater as well as on the substrate to be heated. Additionally as seen in the figures, the spacing between different zones can be varied.

Although the heaters shown in FIG. 4, FIGS. 6A through 6E, and FIG. 7 are shown to have the heating elements (e.g., filaments 612, 614, 712) arranged in rings, in alternate designs, the heating element may be continuous or may be arranged in any other pattern, e.g., radially extending such as spokes, as a grid, discontinuous features such as dots, or as a continuous layer that occupies the entire zone.

The heating elements for the heaters (e.g., the filaments 612, 614, 712) are formed of electrically conductive material and may be, e.g., tungsten, gold, tantalum, molybdenum, carbides and borides of transition metals, etc., but are commonly carbon composites or graphite. The heating elements may be a wire, a tape, or formed from a conductive particulate or powder material.

When the heating elements are filaments, the filaments may be, e.g., 3 mm to 75 mm wide, e.g., 40 mm to 50 mm wide. Split filaments, or those forming two thin annular rings, may be, e.g., 2 mm to 25 mm wide, Of course, thinner and/or thicker filaments may be used, dependent on the system and the desired heating conditions. The distance between adjacent filaments or coils of a filament or coils of a heating element may be, e.g., 10 mm to 50 mm, e.g., 20 mm to 25 mm.

Depending on the material of the disc substrate and the coating to be deposited thereon, the substrate is typically heated to a temperature of 500° C. to 900° C. In order to obtain a consistent temperature gradient across the diameter or radius of the substrate, the outer zone of the heater provides a temperature the same as or greater than the inner zone, in some embodiments at least 10° C., or 50° C., or 100° C. or 150° C. greater. This higher temperature may be obtained by providing more power to the outer zone heating element; as an example, 2 kW are provided to the inner zone and 3.8 kW are provided to the outer zone.

During the heating process, the heating of the two zones may be initiated at the same time or one of the zones may be initiated first. If the heating is initiated at different times, the firstly initiated zone is brought at least partially up to temperature before the other zone is heated. The two zones may be heated at the same or different rates.

The above specification and examples provide a complete description of the structure and use of exemplary implementations of the invention. The above description provides specific implementations and embodiments. It is to be understood that other implementations are contemplated and may be made without departing from the scope or spirit of the present disclosure. Features or elements from one implementation, embodiment or design may be interchanged with other implementations, embodiments or designs unless contrary to the construction. The above detailed description, therefore, is not to be taken in a limiting sense. While the present disclosure is not so limited, an appreciation of various aspects of the disclosure will be gained through a discussion of the examples provided.

Unless otherwise indicated, all numbers expressing feature sizes, amounts, and physical properties are to be understood as being modified by the term “about,” whether or not the term “about” is immediately present. Accordingly, unless indicated to the contrary, the numerical parameters set forth are approximations that can vary depending upon the desired properties sought to be obtained by those skilled in the art utilizing the teachings disclosed herein.

As used herein, the singular forms “a”, “an”, and “the” encompass implementations having plural referents, unless the content clearly dictates otherwise. As used in this specification and the appended claims, the term “or” is generally employed in its sense including “and/or” unless the content clearly dictates otherwise.

Spatially related terms, including but not limited to, “bottom,” “lower”, “top”, “upper”, “beneath”, “below”, “above”, “on top”, “on,” etc., if used herein, are utilized for case of description to describe spatial relationships of an element(s) to another. Such spatially related terms encompass different orientations of the device in addition to the particular orientations depicted in the figures and described herein. For example, if a structure depicted in the figures is turned over or flipped over, portions previously described as below or beneath other elements would then be above or over those other elements.

Since many implementations of the invention can be made without departing from the spirit and scope of the invention, the invention resides in the claims hereinafter appended. Furthermore, structural features of the different implementations may be combined in yet another implementation without departing from the recited claims.

What is claimed is:

1. A heater for a substrate in a deposition system, the heater having a central first heating zone and an annular second heating zone around the first heating zone, each of the heating zones having a power supply, with the heating zones independently controllable.

2. The heater of claim 1 comprising a first filament defining the first heating zone and a second filament defining the second heating zone.

3. The heater of claim 1, wherein the first heating zone is defined by at least two concentric rings.

4. The heater of claim 3, wherein the first heating zone is defined by four concentric rings.

5. The heater of claim 1, wherein the second heating zone is defined by at least one concentric ring.

6. The heater of claim 5, wherein the second heating zone is defined by two concentric rings.

7. The heater of claim 1, wherein the first heating zone and the second heating zone together define a heating area, and the first heating zone occupies at least 50% of the heating area.

8. The heater of claim 7, wherein the first heating zone occupies no more than 80% of the heating area.

9. A heater for a substrate in a deposition system, the heater having a radius and a central first heating zone having an outer radius and an annular second heating zone having an inner radius, the inner radius greater than or equal to the outer radius, with each of the heating zones having an independently controllable power supply.

10. The heater of claim 9 comprising a first filament defining the first heating zone and a second filament defining the second heating zone.

11. The heater of claim 9, wherein the first heating zone is defined by at least two concentric rings.

12. The heater of claim 11, wherein the first heating zone is defined by four concentric rings.

13. The heater of claim 9, wherein the second heating zone is defined by at least one concentric ring.

14. The heater of claim 13, wherein the second heating zone is defined by two concentric rings.

15. The heater of claim 9, wherein the outer radius of the first heating zone is at least 50% of the heater radius.

16. The heater of claim 15, wherein the outer radius of the first heating zone is at least 75% of the heater radius.

17. A method of heating a disc substrate in a deposition system, the method comprising:
bringing a first side of the disc substrate in close proximity to a first heater comprising a central first heating zone having an outer radius and an annular second heating zone having an inner radius, the inner radius greater than or equal to the outer radius, with each of the heating zones having an independently controllable power supply.

18. The method of claim 17 further comprising:
heating the first heating zone to a first temperature, and
heating the second heating zone to a second temperature at least 100° C. greater than the first temperature.

19. The method of claim 17, further comprising bringing a second side of the disc substrate into contact with a second heater comprising a central first heating zone having an outer radius and an annular second heating zone having an inner radius, the inner radius greater than or equal to the outer radius, with each of the heating zones having an independently controllable power supply.

20. The method of claim 19 further comprising:
heating the first heating zone of the second heater to the first temperature, and
heating the second heating zone of the second heater to the second temperature.
